(19) United States
(12) Patent Application Publication
(10) Pub. No.: US 2016/0379709 A1
(43) Pub. Date: Dec. 29, 2016

(54) STORAGE DEVICE

(71) Applicant: KABUSHIKI KAISHA TOSHIBA, Tokyo (JP)

(72) Inventors: Jun HIROTA, Yokohama (JP); Moto YABUKI, Yokkaichi (JP); Hideo SHINOMIYA, Yokohama (JP)

(21) Appl. No.: 15/068,157

(22) Filed: Mar. 11, 2016

Related U.S. Application Data
(60) Provisional application No. 62/184,533, filed on Jun. 25, 2015.

(51) Int. Cl. G11C 13/00

(52) U.S. Cl. CPC G11C 13/0021

(57) ABSTRACT

A storage device has a recording media capable of recording information, a probe array which is arranged opposed to one main surface of the recording media and includes a plurality of probes capable of reading and writing the information from/to the recording media by contacting the probes with or providing the probes adjacent to the one main surface, and an actuator to relatively move the recording media and the probe array along a direction parallel to the one main surface. The probe includes a cantilever which comprises a groove on a surface side opposed to the one main surface and an electrode arranged on at least one side surface connected to the surface opposed to the one main surface of the cantilever.

### CROSS REFERENCE TO RELATED APPLICATIONS

This application is based upon and claims the benefit of priority from the prior U.S. Provisional Patent Application No. 62/184,533 filed on Jun. 25, 2015, the entire contents of which are incorporated herein by reference.

### FIELD

The present invention relates to a storage device.

### BACKGROUND

A storage device has been proposed in which a plurality of probes is arranged opposed to one main surface of recording media and information is written and read by contacting an optional probe with the one main surface.

In the storage device of this kind, since an operation for contacting a tip end part of the probe with the one main surface of the recording media is repeated, the tip end part of the probe is abraded. When shavings of the probe caused by the abrasion interpose between the tip end of the probe and the one main surface, a contact resistance is increased. In some cases, the information cannot normally be read and written.

### BRIEF DESCRIPTION OF THE DRAWINGS

FIG. 1 is a perspective diagram of a storage device according to one embodiment;

FIG. 2 is a perspective diagram of a probe;

FIG. 3 is a perspective diagram of a second part of a cantilever;

FIGS. 4A to 4K are process diagrams of an exemplary manufacturing process for the probe according to the present embodiment;

FIG. 5 is a diagram of an example in which a corner of a projection part is rounded;

FIG. 6 is a diagram of a modification of FIG. 5;

FIG. 7 is a perspective diagram of the probe formed by combining characteristics of FIGS. 5 and 6;

FIGS. 8A and 8B are diagrams of a forming process for the probe in FIG. 7;

FIG. 9 is a perspective diagram of a probe in a case where an electrode is not processed; and

FIG. 10 is a perspective diagram of a second part of a cantilever in FIG. 9.

### DETAILED DESCRIPTION

According to one embodiment, a storage device has a recording media capable of recording information, a probe array which is arranged opposed to one main surface of the recording media and includes a plurality of probes capable of reading and writing the information from/to the recording media by contacting the probes with or providing the probes adjacent to the one main surface, and an actuator to relatively move the recording media and the probe array along a direction parallel to the one main surface. The probe includes a cantilever which comprises a groove on a surface side opposed to the one main surface and an electrode arranged on at least one side surface connected to the surface opposed to the one main surface of the cantilever.

### First Embodiment

Embodiments of the present invention will be described below with reference to the drawings. In the drawings attached to the specification, for easy illustration and easy understanding, the scale and the aspect ratio are appropriately changed and exaggerated from the actual size.

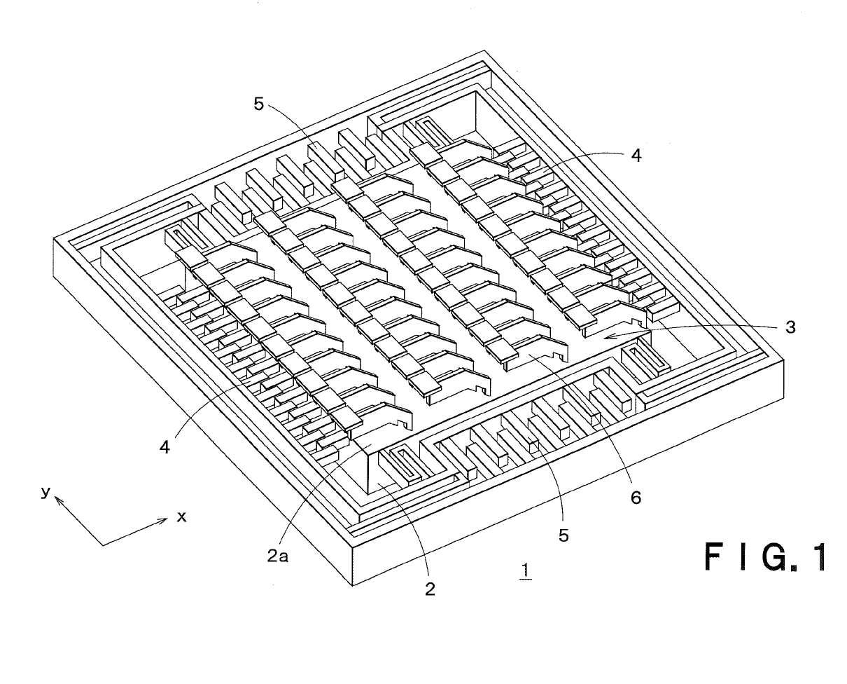

FIG. 1 is a perspective diagram of a storage device 1 according to one embodiment. The storage device 1 in FIG. 1 includes a recording media 2, a probe array 3, a first actuator 4, and a second actuator 5.

The recording media 2 includes a plurality of storage elements which can store information. These storage elements are vertically and horizontally arranged on one main surface 2a. Also, the storage elements may be arranged in a normal direction of the one main surface 2a. The storage element may have any specific element structures. For example, the storage element may be a resistance change memory cell and other nonvolatile memory element. Also, a film which can store the information may be used instead of the storage element.

The probe array 3 includes a plurality of probes 6 arranged opposed to the one main surface 2a of the recording media 2. The probes 6 are arranged as having contact with or adjacent to the one main surface 2a of the recording media 2. A current or a voltage is applied to the probe 6 in a state where an optional probe 6 is positioned on the one main surface 2a of the recording media 2 so that the information is read or written.

The first actuator 4 relatively moves the recording media 2 and the probe array 3 along a first direction x parallel to the one main surface 2a of the recording media 2. The second actuator 5 relatively moves the recording media 2 and the probe array 3 along a second direction y intersecting with the first direction x.

Any specific mechanisms for relatively moving the recording media 2 and the probe array 3 by the first actuator 4 and the second actuator 5 can be used. For example, the first actuator 4 and the second actuator 5 can be formed of an electrostatic actuator. However, an actuator with other system may be employed.

In the storage device 1 in FIG. 1, a direction for recording or reproducing the recording media 2 coincides with a direction for scanning each probe 6 in the probe array 3. Also, a tip end part of each probe 6 is positioned at a desired position on the one main surface 2a of the recording media 2 by using the first actuator 4 and the second actuator 5. Accordingly, the information can be normally read from and written to the recording media 2.

An example will be described below in which the one main surface 2a of the recording media 2 is two-dimensionally moved in a state where the tip end part of the probe 6 is contacted with the one main surface 2a of the recording media 2. When the one main surface 2a is moved in a state where the probe 6 is contacted with the one main surface 2a, shavings are generated by the abrasion of the probe 6. Therefore, the present embodiment has characteristics for applying the countermeasures to it. Even when the probe 6 is arranged adjacent to the one main surface 2a of the recording media 2 and information is read and written, the shavings caused by the abrasion of the probe 6 are sometimes generated by contacting the probe 6 with the one main surface 2a by vibration and the like. Therefore, the present embodiment can be applied to a case where the probe 6 is arranged adjacent to the one main surface 2a of the recording media 2 and the information is read and written.

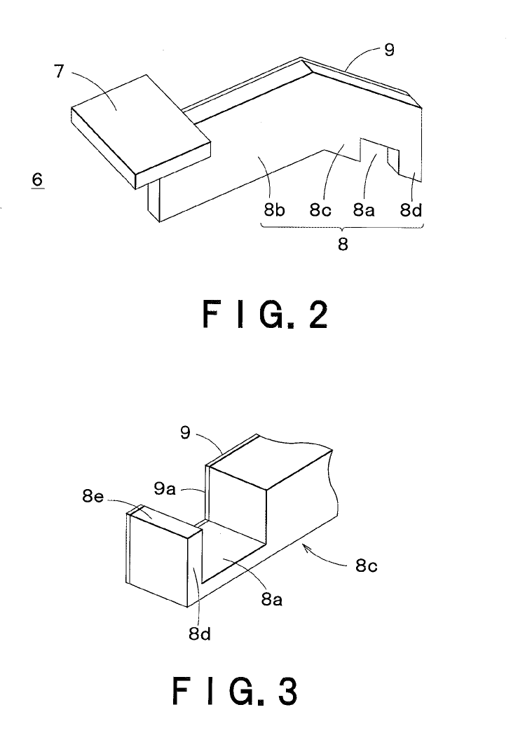

FIG. 2 is a perspective diagram of the probe 6. The probe 6 in FIG. 2 includes a support part 7 which is supported by a supporting substrate, which is not shown, of the probe array 3, an insulating cantilever 8 which is coupled to the support part 7, and an electrode 9 which is arranged on one side surface of the cantilever 8.

The cantilever 8 is extended along the one main surface 2a of the recording media 2, and a groove 8a is provided on a surface side opposed to the one main surface 2a of the cantilever 8. As described below, the groove 8a is used to remove the shavings caused by the abrasion of the probe 6.

The structure of the cantilever 8 will be described below with reference to FIG. 2. The cantilever 8 includes a first part 8b which is coupled to the support part 7 and a second part 8c which is coupled to a side of one end of the first part 8b. The first part 8b is arranged apart from the one main surface 2a of the recording media 2 and is extended along the one main surface 2a. The second part 8c is bent from the first part 8b and is extended in a direction of the one main surface 2a of the recording media 2, and the tip end part of the second part 8c has contact with the one main surface 2a of the recording media 2.

The electrode 9 has a recessed part 9a in a place overlapping with the groove 8a. The recessed part 9a and the groove 8a of the electrode 9 have the same shapes, and the shavings pass through the groove 8a and the recessed part 9a and can cut across the probe 6.

FIG. 3 is a perspective diagram of the second part 8c of the cantilever 8. FIG. 3 is a perspective diagram of a part of the second part 8c viewed from a surface side opposed to the one main surface 2a of the recording media 2. On the surface side opposed to the one main surface 2a of the recording media 2 of the second part 8c, the groove 8a and the projection part 8d are provided. The projection part 8d is projected from the groove 8a to the side of the one main surface 2a of the recording media 2. The projection part 8d is arranged on a side nearer to tip end of the second part 8c than the groove 8a and has contact with the one main surface 2a of the recording media 2. In FIG. 3, a contact surface of the projection part 8d with the one main surface 2a of the recording media 2 is indicated by a reference numeral 8e.

The contact surface 8e has the same plane as one end surface of the electrode 9, and the contact surface 8e and the one end surface of the electrode 9 have contact with the one main surface 2a of the recording media 2. Actually, the electrode 9 is involved in reading and writing the information relative to the recording media 2. Therefore, by reducing the thickness of the electrode 9, the size of the storage element on the recording media 2 can be reduced, and a memory capacity of the recording media 2 can be increased.

The first actuator 4 and the second actuator 5 relatively move the recording media 2 and the probe 6 in a state where the projection part 8d and the electrode 9 of the probe 6 are contacted with the one main surface 2a of the recording media 2. This movement causes the abrasion of the projection part 8d and the electrode 9. The projection part 8d is a part of the cantilever 8, and an insulator is used for the projection part 8d.

Therefore, the projection part 8d generally have a larger abrasion degree than the electrode 9 using a conductive material. When the insulator scraped by the abrasion enters between the electrode 9 and the one main surface 2a of the recording media 2, a contact resistance between the electrode 9 and the one main surface 2a is increased, and there is a case where the information cannot be stably read and written.

Therefore, in the present embodiment, the groove 8a is provided adjacent to the projection part 8d of the cantilever 8, and similarly, the recessed part 9a is provided in the electrode 9. At least a part of the insulator caused by the abrasion of the projection part 8d passes through the groove 8a and the recessed part 9a and is kept away from the electrode 9. Accordingly, the increase in the contact resistance which is caused by the entrance of the shavings formed of the insulator between the electrode 9 and the one main surface 2a of the recording media 2 can be prevented, and the information can be stably read and written.

The size of the shavings caused by the abrasion of the projection part 8d and the electrode 9 of the cantilever 8 depends on the shape and size of the cantilever 8. However, the size of the shavings is generally about 100 to 200 nm. Therefore, it is desirable that the size of the groove 8a provided in the second part 8c of the cantilever 8 be equal to or larger than 100 nm square. That is, it is necessary to set the size of the groove 8a to be equal to or larger than the size of the shavings. When the size of the groove 8a is determined, it is preferable that the size of the shavings be previously measured.

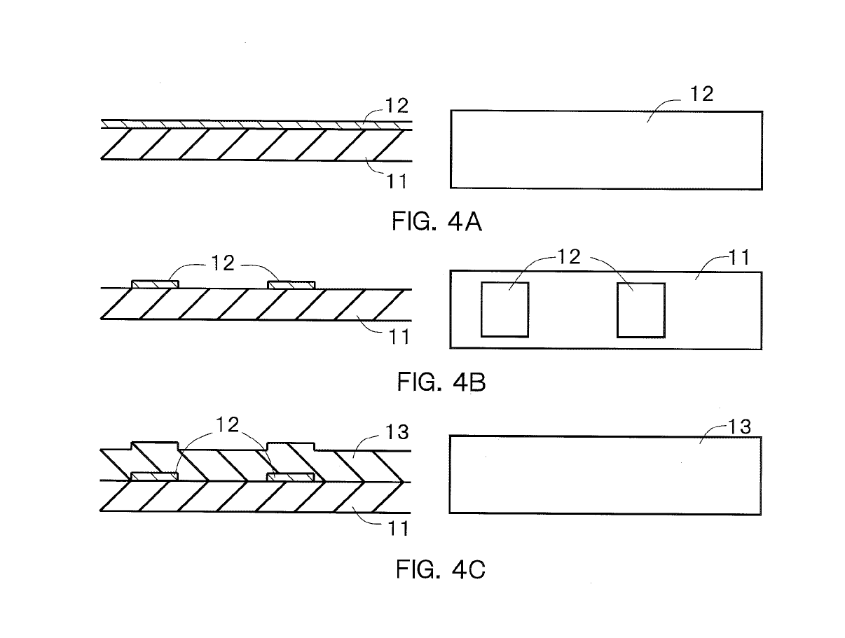

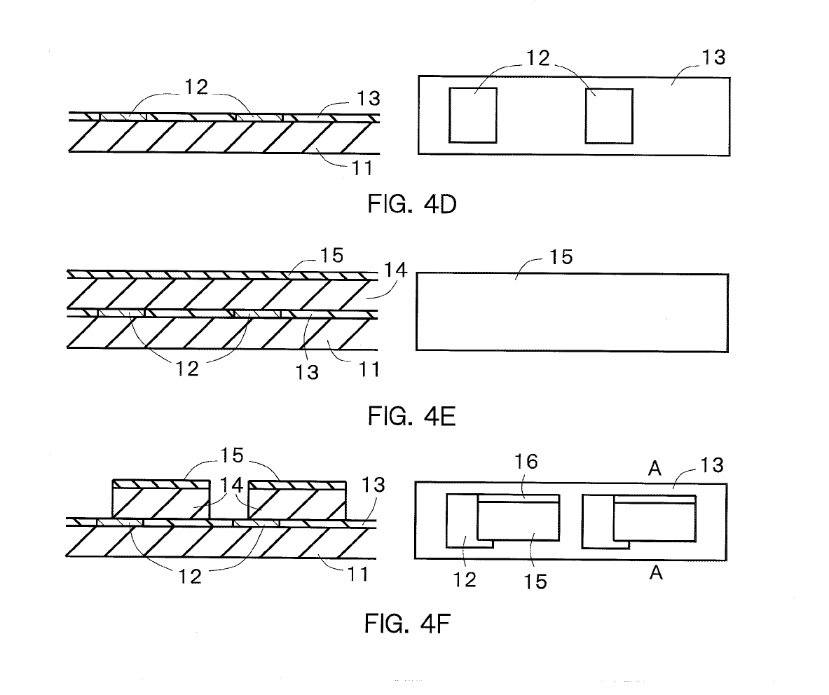

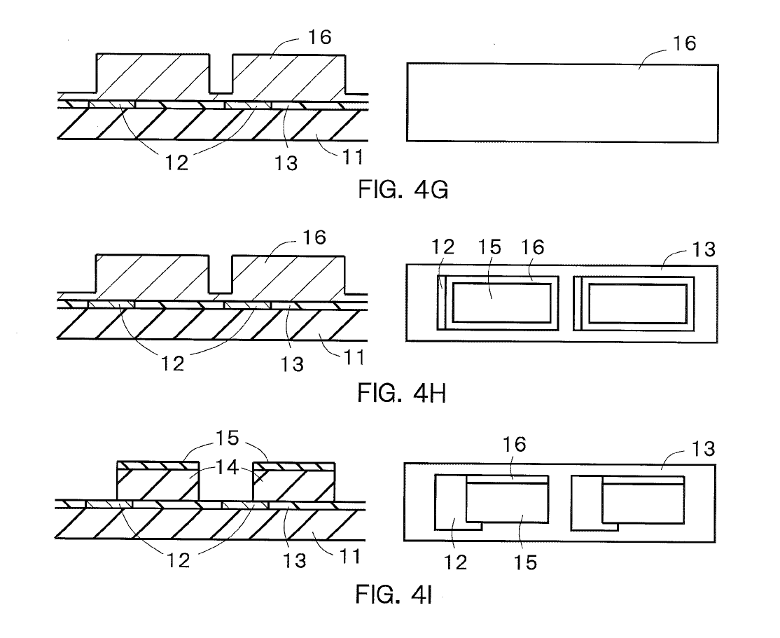

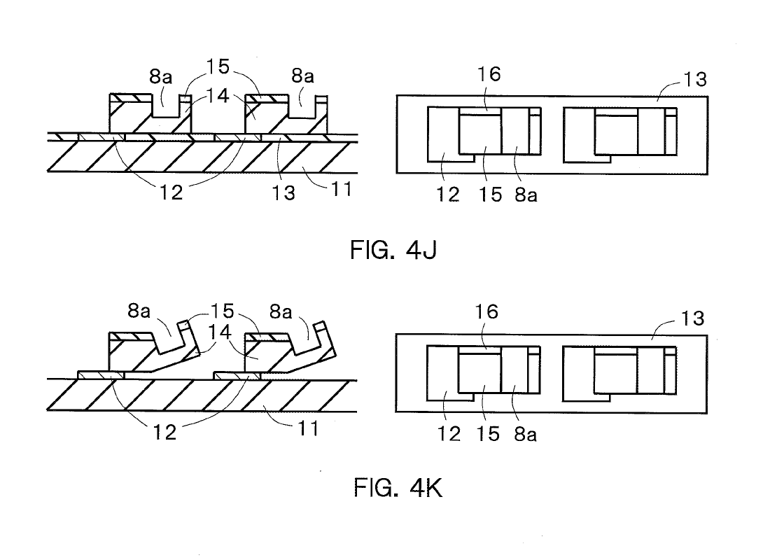

FIGS. 4A to 4K are process diagrams of an exemplary manufacturing process for the probe 6 according to the present embodiment. The left sides of FIGS. 4A to 4K are cross-sectional diagrams, and the right sides are top views.

First, as illustrated in FIG. 4A, a metal film 12 such as tungsten is vapor-deposited on a silicon oxide film 11 formed by using a plasma CVD method. The film thickness of the metal film 12 is, for example, about 20 nm.

Next, as illustrated in FIG. 4B, the metal film 12 is patterned according to the shape of the support part 7 of the cantilever 8.

Next, as illustrated in FIG. 4C, an amorphous carbon composite film 13 is vapor-deposited on the silicon oxide film 11 and the metal film 12. An insulation film may be coated instead of the amorphous carbon composite film 13.

Next, as illustrated in FIG. 4D, a top surface of the amorphous carbon composite film 13 is flattened by using chemical mechanical polishing (CMP), and the silicon oxide film 11 is exposed.

Next, as illustrated in FIG. 4E, a silicon oxide film 14 to be a base material is formed on the flattened surface, and a SiN film 15 to be a warping material is formed on that. The film thickness of the silicon oxide film 14 is about 400 nm, and the film thickness of the SiN film 15 is about 100 nm. The silicon oxide film 14 and the SiN film 15 have different stresses, and the different stresses make the SiN film 15 warp relative to the silicon oxide film 14. Therefore, when the materials have different stresses from each other, an insulation material other than the silicon oxide film 14 and the SiN film 15 may be used.

Next, as illustrated in FIG. 4F, the silicon oxide film 14 and the SiN film 15 are patterned by the lithography and reaction ion etching (RIE). Here, the silicon oxide film 14 and the SiN film 15 are patterned according to the shape of the cantilever 8.

Next, as illustrated in FIG. 4G, regions around the silicon oxide film 14 and the SiN film 15 are covered with a metal film 16 such as W by spattering.

Next, as illustrated in FIG. 4H, a part of the metal film 16 is removed and the SiN film 15 is exposed by the RIE.

Next, as illustrated in FIG. 4I, by the lithography and the RIE, the metal film 16 is left on one side surface of the SiN film 15, and the metal films 16 on the other surfaces are removed. Accordingly, the electrode 9 arranged on the one side surface of the cantilever 8 is completed.

Next, as illustrated in FIG. 4J, by the lithography and the RIE, a part of the SiN film 15, a part of the silicon oxide film 14, and a part of the metal film 16 are removed, and the groove 8a, the recessed part 9a, and the projection part 8d are formed.

Next, as illustrated in FIG. 4K, the amorphous carbon composite film 13 which is a base of the silicon oxide film 14 is removed by O₂ ashing. Accordingly, the difference between the stresses of the SiN film 15 and the silicon oxide film 14 makes the second part 8c including the groove 8a and the projection part 8d warp upward in FIG. 4K.

According to the above processes, the probe 6 according to the present embodiment is completed.

In this way, in the first embodiment, since the groove 8a and the projection part 8d are provided on the tip end side of the probe 6, the shavings of the projection part 8d and the electrode 9 generated by the abrasion caused at the time when the projection part 8d and the electrode 9 of the probe 6 are contacted with the one main surface 2a of the recording media 2 can be guided to the groove 8a and can be kept away from the electrode 9. Therefore, it is possible to avoid a malfunction in that the shavings enter between the electrode 9 and the one main surface 2a of the recording media 2 to increase the contact resistance.

### Second Embodiment

A method for reducing the shavings caused by the abrasion of the projection part 8d and the electrode 9 of the probe 6 is to make the abrasion of the projection part 8d and the electrode 9 hardly occur. To reduce the abrasion without changing the material of the probe 6, a lubricant is effective. By coating the projection part 8d and the electrode 9 of the probe 6 contacting with the one main surface 2a of the recording media 2 with the lubricant, a friction on a contact interface is weakened, and the projection part 8d and the electrode 9 can easily slip. Accordingly, the abrasion of the projection part 8d and the electrode 9 can be prevented, and a total amount of the shavings can be reduced. Since it is necessary to maintain the conductivity of the electrode 9, the lubricant which can secure the conductivity is used. Alternatively, the entire surface of the projection part 8d contacting with the one main surface 2a of the recording media 2 may be coated with the lubricant and the electrode 9 is not coated with the lubricant.

Any specific material of the lubricant can be used, and for example, z-Tetraol used as the lubricant for a hard disk drive can be used.

### Third Embodiment

In order to reduce the shavings of the projection part 8d and the electrode 9 generated by the abrasion caused at the time when the probe 6 is contacted with the one main surface 2a of the recording media 2, it is desirable that a contact area with the one main surface 2a be reduced as possible. Especially, the shavings of the insulator caused by the abrasion of the projection part 8d of the probe 6 have a bad effect on the contact resistance between the electrode 9 of the probe 6 and the one main surface 2a of the recording media 2.

Especially, since the corner of the projection part 8d is pointed, the shavings generated by the abrasion are easily generated. Therefore, in the present embodiment, processing is performed for rounding a part of the contact surface of the projection part 8d with the one main surface, more specifically, the corner of the projection part 8d.

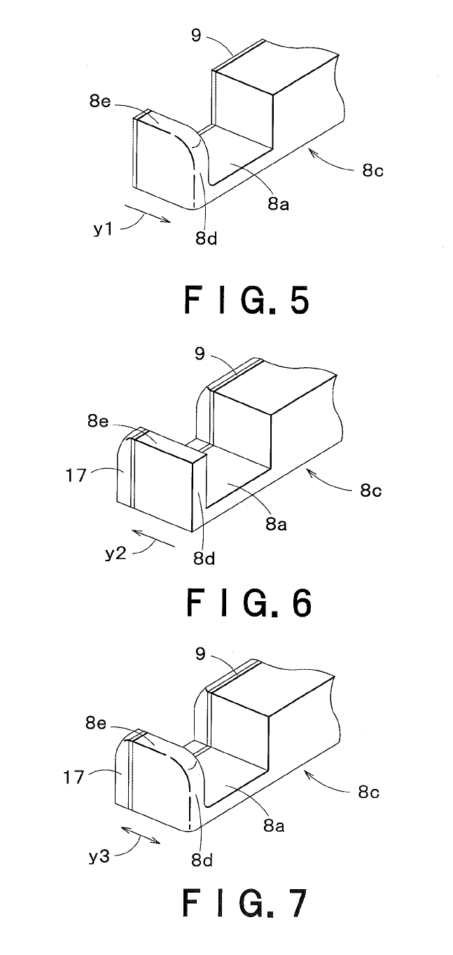

FIG. 5 is a diagram of an example in which the corner of the projection part 8d has been rounded. The corner in FIG. 5 is provided on a surface opposed to the surface where the electrode 9 of the projection part 8d is arranged. By rounding the corner of the projection part 8d, the contact area between the projection part 8d and the one main surface 2a of the recording media 2 can be reduced. In a case of FIG. 5, the shavings at the corner can be smaller than that in a case where a corner is not rounded. Therefore, especially, when the probe 6 is relatively moved relative to the one main surface 2a of the recording media 2 in a direction of an arrow y1 in FIG. 5, the frequency of the entrance of the shavings between the electrode 9 and the one main surface 2a can be reduced.

A process for rounding the corner of the projection part 8d as illustrated in FIG. 5 can be relatively easily performed by excessively performing the RIE to the corner when the silicon oxide film and the SiN film are patterned in the process in FIG. 4F. Alternatively, when the metal film is removed in the process in FIG. 4I, a process for rounding the corner of the projection part 8d by the RIE may be performed together.

In a case where the corner on the opposite side of the electrode 9 of the projection part 8d is rounded as illustrated in FIG. 5, an effect to prevent the bad effect caused by the shavings can be obtained when the probe 6 is relatively moved to a direction y1 of the corner as illustrated in FIG. 5. However, there is almost no effect when the probe 6 is moved to the opposite side (the side of the electrode 9). To reduce the shavings when the probe 6 is moved to the side of the electrode 9, it can be considered that the tip end side of the probe 6 is formed in a shape illustrated in FIG. 6, for example. The corner in FIG. 6 is provided on a surface side where the electrode 9 of the projection part 8d is arranged. More specifically, in FIG. 6, the probe 6 includes an insulator 17 which is arranged opposed to the one side surface of the cantilever 8 and sandwiches the electrode 9 with the one side surface, and at least a part of the contact surface of the insulator 17 with the one main surface is rounded.

In the probe 6 in FIG. 6, the side surface of the electrode 9 arranged on the one side surface of the cantilever 8 is covered with the insulator 17, and a corner of the insulator 17 is rounded. Accordingly, even when the probe 6 is moved in a direction of an arrow y2 in FIG. 6, the amount of the abrasion of the insulator 17 adjacent to the electrode 9 can be reduced.

FIG. 7 is a perspective diagram of the probe 6 formed by combining characteristics of FIGS. 5 and 6. In the probe 6 in FIG. 7, a corner of the projection part 8d is rounded, and a corner of the insulator on a side of the side surface of the electrode 9 is also rounded. Therefore, even when the probe 6 in FIG. 7 is moved in a direction of a double-headed arrow y3 in FIG. 7, the electrode 9 hardly receives the effect of the shavings caused by the abrasion of the insulator.

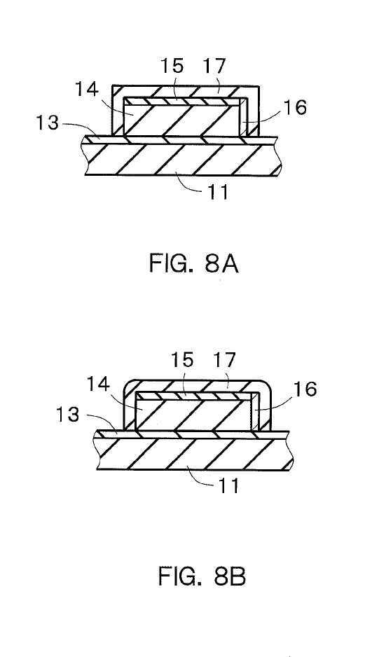

To produce the probe 6 in FIG. 7, for example, after the process in FIG. 4I, a substrate top surface is covered with the SiN 17 as illustrated in FIG. 8A. FIG. 8A is an A-A line cross sectional diagram of FIG. 4I. After that, the SiN is etched back as illustrated in FIG. 8B so that the corner of the projection part 8d can be rounded and the corner of the insulator on the side of the side surface of the electrode 9 can also be rounded.

In this way, in the third embodiment, since the corner of the projection part 8d of the probe 6 is rounded, the contact area of the projection part 8d contacting with the one main surface 2a of the recording media 2 can be reduced, and the total amount of the shavings caused by the abrasion can be reduced.

In the first to third embodiments, an example has been described in which the electrode 9 is arranged on the one side surface of the cantilever 8. However, the electrodes 9 may be arranged on both side surfaces of the cantilever 8. However, when the electrodes 9 are arranged on both side surfaces, it is necessary to contact one of the electrodes 9 with the one main surface 2a of the recording media 2. Therefore, it is desirable that the support part 7 of the probe 6 make the projection part 8d slightly incline and contact with the one main surface 2a. Also, the support part 7 may include an inclination adjusting mechanism which can make the other electrode 9 contact with the one main surface 2a when one electrode 9 is abraded.

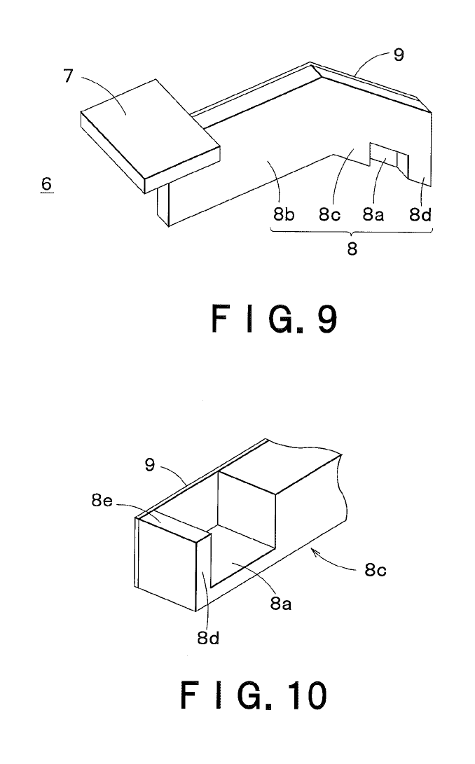

In the first to third embodiments, an example has been described in which the recessed part 9a is provided in the electrode 9 so as to overlap with the groove 8a of the cantilever 8. However, the recessed part 9a does not have to be formed in the electrode 9. The perspective diagram of the probe 6 in this case is as illustrated in FIG. 9, and the perspective diagram of the second part 8c of the cantilever 8 is as illustrated in FIG. 10. In a case of the probe 6 in FIGS. 9 and 10, since it is not necessary to process the electrode 9, the manufacturing process is simplified, and an area of the electrode 9 is increased. Therefore, the conductivity of the electrode 9 is improved, and the contact resistance can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A storage device comprising:
a recording media capable of recording information;
a probe array which is arranged opposed to one main surface of the recording media and includes a plurality of probes capable of reading and writing the information from/to the recording media by contacting the probes with or providing the probes adjacent to the one main surface; and
an actuator to relatively move the recording media and the probe array along a direction parallel to the one main surface, wherein
the probe includes a cantilever which comprises a groove on a surface side opposed to the one main surface and an electrode arranged on at least one side surface connected to the surface opposed to the one main surface of the cantilever.

2. The storage device according to claim 1, wherein
the cantilever comprises a first part which is arranged apart from the one main surface and is extended along the one main surface, and a second part which is coupled to one end side of the first part and is extended to a side closer to the one main surface, and
the groove is provided on a surface side opposed to the one main surface of the second part.

3. The storage device according to claim 2, wherein
the second part comprises a projection part which is arranged on a side nearer to a tip end than the groove and contacts the one main surface.

4. The storage device according to claim 3, wherein
the projection part is arranged on a plane identical to the electrode.

5. The storage device according to claim 1, wherein
the electrode comprises a recessed part arranged at a position overlapped with the groove of the cantilever.

6. The storage device according to claim 3, comprising:
a lubricant arranged on a contact surface to contact the one main surface.

7. The storage device according to claim 1, wherein
a size of the groove is equal to or larger than 100 nm square.

8. The storage device according to claim 3, wherein
a partial contact surface of the projection part with the one main surface is rounded.

9. The storage device according to claim 8, wherein
the partial contact surface is a corner of the projection part.

10. The storage device according to claim 9, wherein
the corner is provided on a surface side of the projection part opposed to the surface where the electrode is arranged.

11. The storage device according to claim 9, wherein
the corner is arranged on a surface side of the projection part where the electrode is arranged.

12. The storage device according to claim 11, wherein
the corner includes an insulator which is arranged opposed to the one side surface and sandwiches the electrode with the one side surface, and
at least a part of a contact surface of the insulator with the one main surface is rounded.

13. The storage device according to claim 9, wherein
the corners are provided on a side opposed to the surface of the projection part where the electrode is arranged and a surface side of the projection part where the electrode is arranged.
